(19) United States
(12) Patent Application Publication
(10) Pub. No.: US 2025/0246518 A1
(43) Pub. Date: Jul. 31, 2025

(54) SUBSTRATE COMPRISING VIAS AND ASSOCIATED MANUFACTURING METHODS

(71) Applicants: COMMISSARIAT A L'ENERGIE ATOMIQUE ET AUX ENERGIES ALTERNATIVES, Paris (FR); SOITEC, Bernin (FR)

(72) Inventors: Jean CHARBONNIER, Grenoble Cedex 09 (FR); Perceval COUDRAIN, Grenoble Cedex 09 (FR); Caroline COUTIER, Grenoble Cedex 09 (FR); Bruno GHYSELEN, Seyssinet Pariset (FR); Thierry SALVETAT, Grenoble Cedex 09 (FR)

(73) Assignees: COMMISSARIAT A L'ENERGIE ATOMIQUE ET AUX ENERGIES ALTERNATIVES, Paris (FR); SOITEC, Bernin (FR)

(21) Appl. No.: 18/854,310

(22) PCT Filed: Apr. 3, 2023
(86) PCT No.: PCT/EP2023/058705

§ 371 Date: Oct. 4, 2024

(30) Foreign Application Priority Data
Apr. 6, 2022 (FR) 2203164

(51) Int. Cl. H01L 23/48; H01L 21/768; H01L 23/31

(52) U.S. Cl. CPC H01L 23/481; H01L 21/76877; H01L 21/76898; H01L 23/3192

(57) ABSTRACT

A substrate is provided, including: a first layer based on a semiconductive material; a second layer surmounting the first layer; and a plurality of buried vias extending from the second layer over a portion of the first layer, each via of the plurality of buried vias being delimited by a side wall, a bottom wall, and an upper wall opposite the bottom wall, each via having at least one transverse dimension less than or equal to 30 μm. A method for manufacturing the substrate is also provided. A method for manufacturing a microelectronic device is also provided.

### TECHNICAL FIELD OF THE INVENTION

The present invention relates to the field of substrates intended to manufacture electronic devices, and more specifically, microelectronic devices, these substrates ultimately enabling an electrical and mechanical connection of electrical elements of components. The invention has an advantageous, but not limiting, application in manufacturing microelectronic devices, and for example, microelectronic devices for calculation applications.

### PRIOR ART

There is an interest in manufacturing, as for example illustrated by FIG. 1, assemblies of components 4′ on substrates 3 comprising vias 32 to form through contacts in order to be able to interconnect these components on the front face 3a and on the back face 3b of the substrate 3, to obtain a microelectronic device 4. The components 4′ can thus be connected to a printed circuit, for example, through a casing 5. These substrates 3 can, in particular, be semiconductive substrates, for example, of the semiconductor-on-insulator, and in particular, silicon-on-insulator (SOI) type.

The etching and the filling of these vias (commonly called TSV (Through-Silicon-Via) with an electrically conductive or semiconductive material, are quite specific steps of the method and often produced at assemblers' premises (commonly called OSAT (Outsourced Semi-conductor Assembly and Test) and not at founders' premises.

Two types of vias are distinguished according to their time of manufacture in the production line of a microelectronic device. So-called “TSV-middle” vias are generally manufactured in the middle of the method, after manufacturing patterns of a component during the Front-end-of-line (FEOL), but before depositing the metal layers of the Back-end-of-line (BEOL). This generally demands a transfer of the substrate and of the components from the founder to the assembler to manufacture vias, then a return to the founder for the BEOL steps, and finally also, a transfer to the assembler to finalise the method. These manufacturing steps are very limited in terms of planarity, of contamination, which is not very compatible with these back-and-forth motions between founder and assembler.

“TSV-last” vias can be manufactured at the end of the method, after the FEOL and BEOL steps. This generally demands one single transfer from the founder to the assembler, after the BEOL steps. However, the via geometries which can thus be achieved are limited. In particular, the via density being able to be obtained is limited. This is particularly limiting for certain applications, such as for calculating.

There is therefore a need to obtain these structures without depending on the other manufacturing steps of the line.

An aim of the present invention is therefore to facilitate the manufacture of vias in a microelectronic device.

Other aims, features and advantages of the present invention will appear upon examining the description below and the accompanying drawings. It is understood that other advantages can be incorporated.

### SUMMARY OF THE INVENTION

To achieve this aim, according to an embodiment, a substrate is provided, comprising:
a first base layer, and preferably made of a semiconductive material,
a second layer surmounting the first layer.

Advantageously, the substrate comprises a plurality of buried hollow vias extending from the second layer over a portion of the first layer, each via being delimited by a side wall, a bottom wall, and an upper wall opposite the bottom wall.

Thus, the substrate comprises non-opening hollow vias for the subsequent filling with an electrically conductive or semiconductive member. This makes it possible to provide the hollow vias independently of the other steps of producing a microelectronic device. The substrate comprising the buried hollow vias can be used to carry out the deposition of layers, for example, FEOL and BEOL, then the hollow vias can be open to produce the desired electrically conductive or semiconductive member, for example, electrical interconnections. Furthermore, with the vias being manufactured beforehand, the geometries of the vias are not limited.

This has several advantages. These hollow vias are compatible with the FEOL steps taking place at a high temperature, contrary to the current solutions implementing metallised vias, for example, made of copper or of tungsten.

It is therefore understood that manufacturing the vias is facilitated, in particular regarding the other steps of manufacturing a microelectronic device. Manufacturing the vias filled with the electrically conductive or semiconductive member, is more particularly facilitated.

According to an example, at least the bottom wall and the side wall are made of dielectric material. With the dielectric material walls being formed beforehand, they enable a good isolation of the vias once filled with the conductive or semiconductive material, while being compatible with the FEOL steps, or step of temporarily mounting a support. This is particularly advantageous when the form factor of the vias is greater than or equal to 10, for which it is simpler to produce these walls prior to manufacturing a microelectronic device.

A second aspect relates to a method for manufacturing the substrate according to the first aspect, comprising:
a provision of a support sub-substrate comprising at least one first layer with the basis, preferably made, of a semiconductive material, the support sub-substrate having an exposed surface,
an etching of a plurality of vias, such that the vias extend from the exposed surface over a portion of the first layer, each via being delimited by a side wall and a bottom wall,
a provision of a donor sub-substrate comprising a superficial layer having an exposed surface,
an assembly of the support sub-substrate and of the donor sub-substrate by their exposed surfaces, so as to cover the vias, each via thus being delimited by the side wall, the bottom wall, and an upper wall opposite the bottom wall.

This method thus enables the manufacturing of buried hollow vias on the substrate. This method has the effects and advantages described relative to the first aspect.

A third aspect relates to a method for manufacturing a microelectronic device comprising:
a provision of a substrate according to the first aspect or of a substrate manufactured by the method according to the second aspect, having a front exposed surface and a back exposed surface,
a formation of at least one layer portion of the device by a deposition, on the front exposed surface of the substrate, of said portion, and/or an etching of the front exposed surface of the substrate, configured so as to form said portion,
at at least one via, an etching by the back exposed surface of the substrate, in which a wall from among the upper wall and the bottom wall of the at least one via is etched so as to open into the via, then continue the etching to reach the at least one layer portion of the device, to form a cavity,
the deposition of an electrically conductive or semiconductive member, so as to fill the cavity.

Thus, the substrate provided enables the formation of a microelectronic device, then the opening of the buried hollow vias to produce the desired electrically conductive or semiconductive member. This can be done in a facilitated manner with respect to the current solutions.

### BRIEF DESCRIPTION OF THE FIGURES

The aims, objectives, as well as the features and advantages of the invention will best emerge from the detailed description of an embodiment of the latter, which is illustrated by the following accompanying drawings.

FIG. 1 represents a transverse cross-sectional view of a microelectronic device comprising a substrate comprising vias, according to a general example of the prior art.

FIGS. 2A to 2C represent transverse cross-sectional and top views of the substrate according to two examples of embodiments.

FIGS. 3A and 3B each represent a transverse cross-sectional view of the substrate according to two other examples of embodiments, in which the substrate comprises grooves surrounding the vias.

FIG. 3C represents a top view of the substrate illustrated according to any one from among FIGS. 3A and 3B.

FIGS. 4A to 9C represent transverse cross-sectional views of the steps of the method for manufacturing the substrate according to examples of embodiments, from among which:

FIGS. 6A and 6B represent transverse cross-sectional views of the etching and of the formation of the dielectric material walls, according to an example of an embodiment,

FIG. 6C represents a transverse cross-sectional view of the etching of the vias, according to another example of an embodiment,

FIGS. 7A to 7C represent transverse cross-sectional views of the etching and of the formation of the dielectric material walls, according to two other examples of embodiments in which the substrate comprises grooves surrounding the vias.

FIGS. 8A and 8B represent transverse cross-sectional views of the assembly of the support sub-substrate and of the donor sub-substrate according to an example of an embodiment,

FIGS. 9A and 9B represent transverse cross-sectional views of the assembly of the support sub-substrate and of the donor sub-substrate according to another example of an embodiment,

FIG. 9C represents a transverse cross-sectional view of the assembly of the support sub-substrate and of the donor sub-substrate according to another example of an embodiment.

FIGS. 10 to 17 represent transverse cross-sectional views of the steps of the method for manufacturing the microelectronic device according to examples of embodiments, from among which:

FIGS. 10 and 11 represent transverse cross-sectional views of the deposition of device layer portion and of the mounting of a support, according to an example of an embodiment,

FIGS. 12A to 12D represent transverse cross-sectional views of an example of selecting vias to be etched,

FIGS. 12E to 12H represent transverse cross-sectional views of a second example of selecting vias to be etched,

FIGS. 13A to 13C represent transverse cross-sectional views of a third example of selecting vias to be etched,

FIGS. 14A to 14F represent transverse cross-sectional views of an example of the method in which the substrate comprises grooves surrounding the vias,

FIGS. 15 to 17 represent transverse cross-sectional views of the steps according to the deposition of the conductive or semiconductive member, according to an example of an embodiment.

The drawings are given as examples and are not limiting of the invention. They constitute principle schematic representations intended to facilitate the understanding of the invention and are not necessarily at the scale of practical applications. In particular, the relative dimensions of the sub-substrates and substrate, of the layers, of the vias and of the walls are not representative of reality.

### DETAILED DESCRIPTION OF THE INVENTION

Before starting a detailed review of embodiments of the invention, optional features are stated below which can optionally be used in association or alternatively.

According to an example, the second layer is a base layer, and preferably made, of a material chosen from among a dielectric material, for example, an oxide, a semiconductive material or a piezoelectric material.

According to an example, the second layer is a dielectric material layer, for example, an oxide, buried, surmounted by a third layer based on a material chosen from among a semiconductive material or a piezoelectric material. The substrate can be of the “semiconductor-on-insulator” type, and for example, of the “silicon-on-insulator” type.

According to an example, all the transverse dimensions of each via are substantially less than or equal to 30 μm.

According to an example, each via has at least one transverse dimension, for example, a diameter, substantially of between 1 μm and 30 μm. According to an example, all the transverse dimensions of each via are of between 1 μm and 30 μm.

According to an example, at least some of the vias has a form factor greater than or equal to 10, of longer dimensions oriented along a dimension in thickness of the first and second layers. This form factor is particularly adapted to obtain a large via density on the substrate, and in particular, in synergy with the pitch value ranges stated above.

According to an example, the plurality of vias comprises at least three vias, preferably at least five vias.

According to an example, the plurality of vias forms a periodic matrix. Thus, the substrate comprises a hollow via matrix, that it is possible to select, in order to achieve the desired interconnections. The generic substrate comprising these vias therefore make it possible to facilitate the manufacturing of the vias and of the conductive or semiconductive member, by being able to, in particular, be adapted to different microelectronic devices.

According to an example, the vias are separated in pairs by a constant pitch along at least one direction of the main extension plane of the first and second layers.

According to an example, the pitch is substantially between 50 μm and 300 μm, preferably between 100 μm and 200 μm. This pitch enables a better density of the hollow vias in the substrate. Thus, a greater interconnecting density is possible. Furthermore, the adaptability of the substrate to different microelectronic devices is improved.

According to an example, the vias are parallel to one another.

According to an example, the vias have a longitudinal dimension oriented along a dimension in thickness of the first and of the second layer.

According to an example, the vias extend along a direction parallel to the normal to the main extension plane of the first and second layers.

According to an example, the vias are cylindrical. Thus, the bottom wall of the vias is more homogenous than for non-cylindrical shapes, for example, a square shape for which the corners will be shallower than the centre, following the etching of the vias. A cylindrical shape minimises this effect. Furthermore, the mechanical stresses are lower for cylindrical vias which do not have the singularities of the corners. It is advantageous for the heat treatment during the manufacturing of the circuits.

According to an example, the second layer surmounts the first layer by being directly in contact with it.

According to an example, and as it clearly emerges from the figures accompanying the application, at least some of the vias, and preferably each via, has a transverse cross-section, for example, in a plane substantially parallel to the main extension plane of the first and second layers, the ratio of which of the largest dimension over the smallest dimension is less than or equal to 3, preferably less than or equal to 2. The vias are therefore absolutely distinguished from other structures, such as trenches.

According to an example, at least one via, and preferably each via, over at least one portion of a longitudinal dimension of said via, is fully surrounded by a groove extending from the second layer over a portion of the first layer. The groove makes it possible to improve the electrical isolation between the vias. The groove is thus manufactured beforehand and independently of the other steps of manufacturing the microelectronic device. The groove is thus compatible with the FEOL steps taking place at a high temperature. Furthermore, with the groove being manufactured beforehand, its geometry is not limited by the other steps of manufacturing the microelectronic device.

According to an example, each groove is not filled with a solid material. Each groove is preferably filled with an electrically isolating gaseous atmosphere, for example, air, nitrogen or argon, optionally at a pressure less than or equal to the ambient pressure.

According to an example, each groove is delimited by a bottom wall, a side wall and an upper wall opposite the bottom wall. For at least one groove, and preferably for each groove, at least one part of the side wall and the bottom wall can be made of the same material as that of the first layer. The isolation of the vias is indeed sufficient, thanks to the isolating atmosphere contained in the groove. Alternatively, for at least one groove, and preferably for each groove, at least one part of the side wall and the bottom wall can be made of dielectric material, for example, the same dielectric material as the walls of the via. Thus, the electrical isolation of the via is also improved.

According to an example, the groove is concentric to said via. This makes it possible, in particular, to decrease the interfering capacity between the vias and the substrate, and to increase the breakdown voltage.

According to an example, the groove extends from the second layer into the first layer over a longitudinal dimension less than or equal to the longitudinal dimension of the via, preferably plus or minus 5 μm. Thus, the groove surrounds the via over at least one portion and preferably substantially the entire longitudinal dimension.

According to an example, the substrate further comprises a marker configured so as to enable the alignment of the substrate. This makes it possible to also facilitate the manufacturing of the microelectronic device, by facilitating the alignment of the substrate, and in particular, for carrying out the photolithographic steps necessary for the construction of the FEOL and of the BEOL, and therefore, the opening of the vias.

According to an example, the semiconductive material is chosen from among the group consisting of silicon Si, germanium Ge, SiGe, a III-V material (for example, GaN, InN, InGaAs, GaP, InP, InAs, AsGa, etc.), a II-VI material, wide band gap materials, for example, greater than 3 eV.

According to an example, the semiconductive material comprises, and preferably is, silicon.

According to an example, the piezoelectric material is chosen from among lithium tantalate (LiTaO₃), lithium niobate (LiNbO₃), potassium sodium niobate (KₓNa₁₋ₓNbO₃ or KNN), barium titanate (BaTiO₃), quartz, lead zirconate titanate (PZT), a lead magnesium and lead titanate niobate compound (PMN-PT), zinc oxide (ZnO), aluminium nitride (AlN) or aluminium scandium nitride (AlScN).

According to an example, the dielectric material is a semiconductive oxide, and preferably silica of chemical formula SiO₂.

According to an example, following the etching of the plurality of vias and preferably before the assembly of the support sub-substrate and of the donor sub-substrate, the method comprises, for each via, a formation of a dielectric material at at least the bottom wall and the side wall. Thus, the hollow vias formed in the substrate have a dielectric layer at least on their bottom wall and side wall, prior to using the substrate in a method for manufacturing a microelectronic device.

According to an example, the formation of a dielectric material at at least the bottom wall and the side wall of the plurality of vias comprises:
a thermal oxidation, so as to oxidise the semiconductive material of the first layer at at least the bottom wall and the side wall, and/or
a deposition of the dielectric material at at least the bottom wall and the side wall.

These techniques, and quite specifically, thermal oxidation, make it possible to obtain a good conformity of the dielectric material walls. With thermal oxidation being conform, it makes it possible to obtain an oxide which is both dense and of uniform thickness on the bottom and side walls. Thermal oxidation is therefore particularly advantageous in synergy with high via form factors. With respect to a deposition, thermal oxidation further enables a smoothing of the etched via wall and limits the presence of defects between the semiconductive material of the first layer and the dielectrics.

According to an example, when the bottom wall is made of dielectric material, the bottom wall of the plurality of vias has a transverse dimension substantially between 50 nm and 600 nm, preferably substantially equal to 400 nm.

According to an example, when at least the bottom wall and the side wall are made of dielectric material, the side wall of the plurality of vias has a transverse dimension substantially of between 50 nm and 600 nm, preferably substantially equal to 400 nm.

According to an example, the superficial layer of the donor sub-substrate is a layer with the basis, and preferably made, of a material chosen from among a dielectric material, for example, an oxide, a semiconductive material or a piezoelectric material.

According to an example,
the support sub-substrate further comprises a superficial layer with the basis, and preferably made, of a dielectric material, for example, an oxide, surmounting the first layer (10), the superficial layer having the exposed surface, and/or
the superficial layer of the donor sub-substrate is a layer with the basis, and preferably made, of a dielectric material, for example, an oxide, surmounting a layer based on a material chosen from among a semiconductive material or a piezoelectric material.

It is therefore understood that the buried oxide layer of the substrate can come from the donor sub-substrate and/or from the support sub-substrate.

According to an example, the superficial layer of the donor substrate is with the basis, preferably made, of one from among a semiconductive material or a dielectric material. According to which, the superficial layer is based on a semiconductive material or a dielectric material, it is understood that the upper wall of the vias, and if necessary, of the grooves, is based on made of a semiconductive material or of a dielectric material.

According to an example, the etching of the plurality of vias is configured, so as to form a periodic matrix. The effects and advantages described relative to the via matrix are therefore obtained.

According to an example, the method for manufacturing the substrate further comprises, prior to the assembly of the support sub-substrate and of the donor sub-substrate, an etching of a groove fully surrounding at least one via on at least one portion of a longitudinal dimension of said via, the groove extending from the superficial layer into the first layer. The effects and advantages described relative to the groove are therefore obtained.

According to an example, the method comprises a formation of an embrittlement zone at a depth of the surface of the superficial layer of the donor substrate, then a separation of the donor substrate at the embrittlement zone.

According to an example, the method for manufacturing the microelectronic device comprises, prior to the etching by the back exposed surface of the substrate, a selection of at least one via to be etched from among the plurality of vias comprising:
the application, on the back exposed surface of the substrate, of a mask comprising opening located in vertical alignment with the at least one via to be etched, and
an etching of the first layer, so as to reach said wall of the at least one via to be etched.
Thus, it is possible to select the vias to be etched from among the present vias. The method can thus be adapted according to the desired microelectronic device configuration. This selection is particularly advantageous in synergy with the feature according to which the vias form a via matrix.

According to an example, the selection of at least one via to be etched comprises the application of the mask, then the etching of the first layer through the openings of the mask. Thus, a potential embrittlement of the wall of the vias to be etched is avoided. This etching thus etches the first layer to the right of the at least one via to be etched until opening into the at least one via to be etched.

According to an example, the selection of the at least one via to be etched comprises the etching of the first layer, so as to reach said wall of the at least one via to be etched, then the application of the mask. Thus, the dielectric material side wall can be present all along the longitudinal dimension of the cavity which will be formed. It is not necessary to isolate the portion of the cavity to complete the dielectric material wall of the via. The first layer is more specifically etched over all of its main extension plane.

According to an example, the deposition of the electrically conductive or semiconductive member is configured, so as to further cover by an electrically conductive or semiconductive layer, at least one portion of the back exposed surface of the substrate.

According to an example, the method comprises a production of patterns in the electrically conductive or semiconductive back layer.

According to an example, the method comprises the passivation of the back exposed surface of the substrate.

According to an example, the method for manufacturing a microelectronic device comprises:
between the formation of the at least one layer portion of the device, and the etching by the back exposed surface of the substrate, the mounting of a support on the front exposed surface of the substrate, and
after the deposition of the electrically conductive or semiconductive member, so as to fill the electrical cavity, the dismounting of the support.
The support thus makes it possible to facilitate the handling of the substrate.

By microelectronic device, this means any type of device produced with the microelectronic means. These devices include, in particular, in addition to devices with a purely electronic purpose, micromechanical or electromechanical devices, as well as optical or optoelectronic devices. This can be a device intended to ensure an electronic, optical, mechanical function, etc. This can also be an intermediate product only intended to produce another microelectronic device. This can also be a passive electrical interconnecting structure.

It is specified that, in the scope of the present invention, the term “on” or “above” does not compulsorily mean “in contact with”. Thus, for example, the deposition of a layer on another layer, does not compulsorily mean that the two layers are directly in contact with one another, but this means that one of the layers covers the other at least partially, either directly in contact with it, or by being separated from it by a film, also another layer or another element.

A layer can moreover be composed of several sublayers of one same material or of different materials.

By an element “based on” a material A, or A-based, this means an element comprising this material A only, or this material A and optionally other materials.

In the detailed description below, use can be made of terms such as “longitudinal”, “transverse”. These terms must be interpreted relative to the substrate or to the dimension in thickness of the devices. Thus, a longitudinal dimension, a height, a depth or a thickness of an element or of a layer means a dimension along the thickness of the substrate which carries it or contains it. A width, or also a cross-section or a transverse dimension means a dimension perpendicular to the thickness of the substrate.

Certain parts of the substrate or of the device of the invention can have an electrical function. Some are used for electrical conduction properties, and by electrically conductive or equivalent, this means, elements formed of at least one material having a sufficient conductivity, in the application, to carry out the desired function. Other parts, on the contrary, are used for electrical isolation properties and all materials having a sufficient resistivity to achieve this isolation are concerned, and are, in particular, called dielectric or electrically isolating.

The word “dielectric” qualifies more specifically a material of which the electrical conductivity is sufficiently low in the given application to serve as an insulator. In the present invention, a dielectric material preferably has a dielectric constant of less than 4.

By “direct bonding”, this means a bonding without adding adhesive material (of the glue or polymer type, in particular) which consists of the contacting of relatively smooth surfaces (of a Root Mean Square (RMS), of typically less than 5 Å, 10⁻¹⁰ m), for example, achieved at ambient temperature and under ambient atmosphere, in order to create an adherence between them.

According to an embodiment, the direct bonding of two substrates means that the bonding is obtained by chemical bonds which are established between the two contacted surfaces. These chemical bonds can be, for example, Van der Waals bonds and/or strong, covalent chemical bonds, in particular when the bonding is enhanced by a plasma activation, or followed by a reinforcing heat treatment (typically 200 to 1200° C. for 1 hour).

The direct bonding can be obtained without requiring the application of a significant pressure on the structure to be assembled. A slight pressure can simply be applied to initiate the bonding. A thermal annealing can further be carried out to reinforce the bonding.

By a parameter which is “substantially equal to/greater than/less than” a given value, this means that this parameter is equal to/greater than/less than a given value, plus or minus 10%, even plus or minus 5%, of this value.

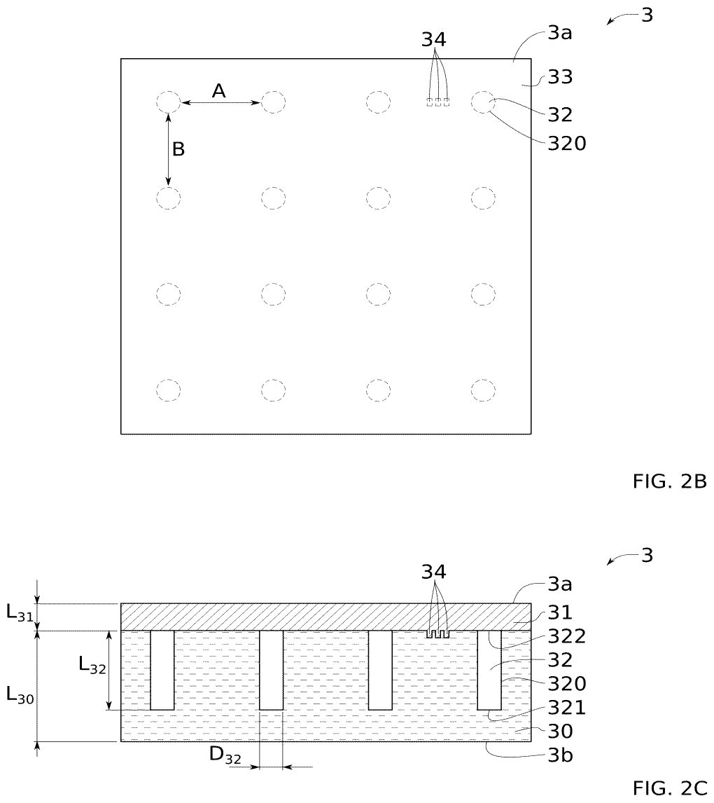

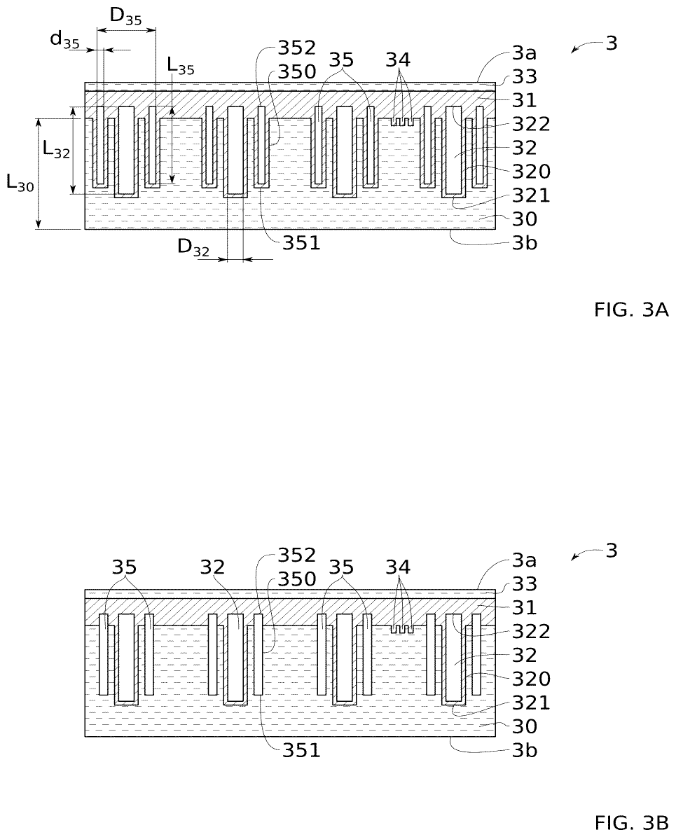

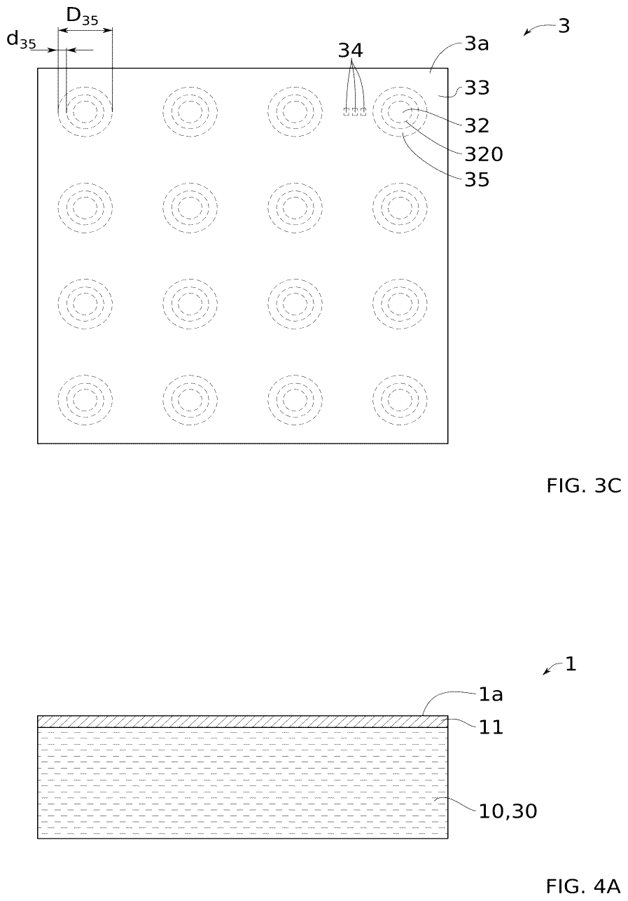

The substrate 3 is now described according to several examples of embodiments in reference to FIGS. 2A to 3C.

As, for example, illustrated by FIG. 2A, the substrate 3 comprises a first layer 30, with the basis or made of a semiconductive material. According to an example, the semiconductive material comprises, and preferably is, silicon. As described below, it is noted that other semiconductive materials can be considered. The first layer 30 has a thickness L₃₀, for example, substantially between 100 μm and 800 μm.

The substrate 3 further comprises a second layer 31. As illustrated by FIG. 2A, the second layer 31 can be with the basis or made of a dielectric material. According to an example, the dielectric material comprises, and preferably is, a semiconductive oxide, for example, silica of formula SiO₂. The second layer 31 surmounts the first layer 30, preferably by being directly in contact with it. As illustrated by FIG. 2B, the second layer 31 can alternatively be with the basis or made of a semiconductive material, preferably monocrystalline, or of a piezoelectric material. The second layer 31 can have a thickness L₃₁, for example, greater than or equal to 10 nm, preferably 100 nm. The thickness L₃₁ can be less than or equal to 3000 nm. The second layer 31 of the substrate 3 preferably has no metal portions. The second layer 31 is preferably continuous in the main extension plane of the substrate 3.

According to an example, being able to be illustrated by FIG. 2A, the second layer 31 is surmounted by a third layer 33 with the basis or made of a semiconductive material, preferably monocrystalline, or of a piezoelectric material. According to an example, the semiconductive material comprises, and preferably is, silicon. In this case, as described below, it is also noted that other semiconductive materials can be considered. The third layer 33 has a thickness L₃₃, for example, substantially between 10 nm and 1000 nm. The substrate 3 can therefore comprise a structure of the semiconductor-on-insulator-type, and in particular of the silicon-on-insulator (SOI)-type. It is noted that it can be provided that the second layer 31 is not surmounted by a third semiconductive layer. The third layer 33 of the substrate 3 preferably has no metal portions. The third layer 33 is preferably continuous in the main extension plane of the substrate 3.

According to an example, the material based on which a layer 30, 31, 33 is formed, is preferably continuous in the extension plane of the layer. At least one and preferably each layer(s) 30, 31 33 is preferably continuous over at least 80%, preferably over at least 90%, and even more preferably all, of the main extension plane of the substrate 3.

The first layer 30 and/or the second layer 31 is/are preferably monolithic. The first layer 30 is preferably monolithic over at least the portion over which the vias 32 extend.

Below, unless explicitly mentioned on the contrary, it is considered in a non-limiting manner, that the substrate 3 is an SOI substrate, the first layer 30 being made of monocrystalline silicon, the second layer made of SiO₂ and the third layer made of monocrystalline silicon.

The substrate 3 comprises hollow vias 32 extending from the second layer 31 into the first layer 30. In a manner known for a person skilled in the art, a via is an interconnecting hole in a substrate. Vias are therefore absolutely distinguished from other structures such as trenches. Vias 32 can be parallel to one another. The vias 32 preferably extend over a longitudinal dimension L₃₂ oriented in the direction of the thickness of the first 30 and second 31 layers. The vias 32 are buried in the substrate 3, i.e. that they do not open onto one or the other of the exposed surfaces 3a, 3b of the substrate 3. The vias 32 therefore define a closed volume, and more specifically, each via 32 therefore defines a closed volume, as it clearly emerges from the figures. The vias 32 do not communicate with one another, as it clearly emerges from the figures. With the vias 32 being hollow, they are not filled with a solid material. They are preferably filled with a gaseous atmosphere such as air, nitrogen and/or argon, optionally at a pressure less than or equal to the ambient pressure.

Thus, the substrate 3 comprises hollow vias 32 for a subsequent filling. This makes it possible to provide the hollow vias independently of the other steps of producing a microelectronic device 4, as described below in reference to the method for manufacturing a microelectronic device.

The longitudinal dimension L₃₂ can be chosen so as to extend over at least one portion of the thickness L₃₁ of the second layer, and only one portion of the thickness L₃₀ of the first layer 30, as for example, illustrated in FIG. 2A. In a variant, the vias 32 can be flush with the surface of the first layer 30, as for example, illustrated in FIG. 2C.

The vias 32 are delimited by a side wall 320, a bottom wall 321 and an upper wall 322 opposite the bottom wall 321. The bottom wall 321 is disposed towards the back surface 3b of the substrate 3 and the upper wall 322 is disposed towards the front surface 3a of the substrate 3.

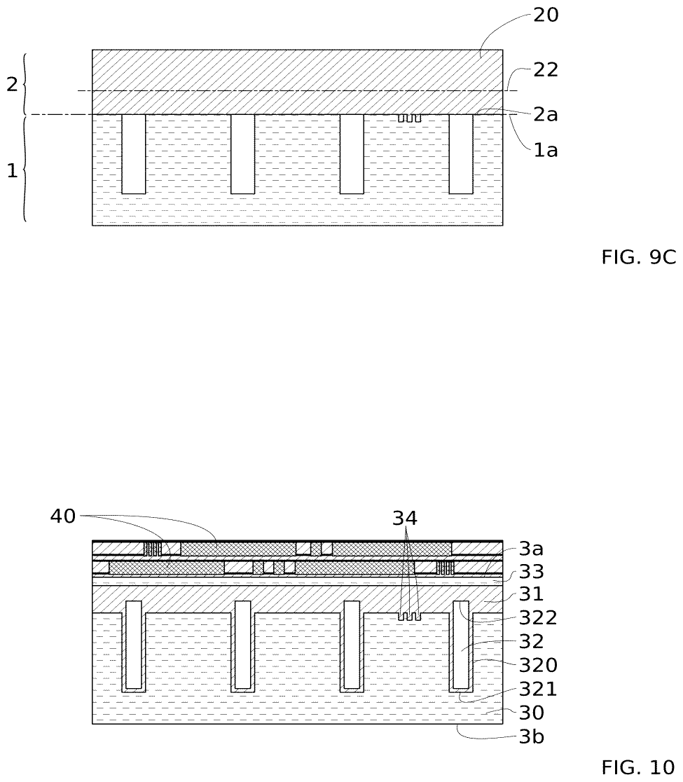

From among these walls, at least the bottom wall 321 and the side wall 320 can be made of dielectric material, for example, made of SiO₂. Thus, the via 32 once filled with an electrically conductive or semiconductive material will be electrically isolated from the first layer 30 and from the other vias 32. As FIG. 2A illustrates, all the walls of the vias 32 can be made of dielectric material. According to a variant, the upper wall 322 can be made of the same material as the third layer 33, as for example, illustrated in FIG. 9A described in detail below in reference to the method for manufacturing the substrate 3.

In a variant, as for example, illustrated by FIG. 2C, the walls of the vias 32 can be made of semiconductive material, and more specifically, of the same material as that of the first layer 30. The electrical isolation of the vias 32 can be done subsequently during the method for manufacturing the microelectronic device from the substrate 3, described below.

The vias can have a transverse dimension D₃₂, for example, a diameter, substantially less than or equal to 30 μm, preferably substantially between 1 μm and 30 μm, preferably substantially between 5 μm and 15 μm, and even more preferably, between 8 and 12 μm. Thus, the side dimension D₃₂ is less than the typical dimensions of TSV-lasts, which makes it possible to have a greater number of vias 32 for one same surface of the substrate 3 in the main extension plane of the first 30 and second 31 layers, i.e. a greater via 32 density. The longitudinal dimension of the vias L₃₂ can be around the thickness L₃₀ of the layer 30, the vias 32 being non-opening. L₃₂ can be substantially less than or equal to 200 μm, preferably substantially between 50 and 150 μm, for example, substantially equal to 100 μm. These length ranges make it possible to facilitate the formation of an electrically conductive or semiconductive through member, for example, a through interconnection through the via 32, of the substrate 3 during the manufacturing of the microelectronic device 4.

The vias 32 can have a form factor substantially greater than or equal to 5, and preferably greater than or equal to 10. By form factor, this means the ratio between the longest dimension over the shortest dimension. In this case, the form factor F is such that F=L₃₂/D₃₂. This form factor makes it possible to facilitate the formation of an electrically conductive or semiconductive through member, for example, a through interconnection through the via 32, during the manufacturing of the device, and to increase the via 32 density on the substrate, in synergy with the pitch separating them.

According to an example being able to be illustrated by FIG. 2B, the vias 32 form a periodic matrix, i.e. that the vias 32 are disposed at regular intervals in the main extension plane of the first 30 and second 31 layers. Thus, the substrate 3 can be a generic substrate comprising a via matrix, in which vias 32′ to be etched and to be filled will be chosen according to the electrically conductive or semiconductive members to be formed, as described in more detail below.

For this, the vias 32 can be separated in pairs by a first pitch A along a first direction contained in the main extension plane of the first 30 and second 31 layers. The vias 32 can be separated in pairs by a second pitch B along a second direction contained in the main extension plane of the first 30 and second 31 layers, distinct from the first. Preferably, these first and second directions are perpendicular. One or the other of these pitches A and B can be substantially between 50 μm and 300 μm, preferably between 100 μm and 200 μm. These pitches can be different from one another or equal to one another, along the desired matrix geometry. This pitch is measured centre-to-centre between two vias 32 following one another directly. The pitches A and/or B are preferably constant, i.e. substantially identical for each pattern repetition.

According to a preferable example, the substrate 3 comprises one single via 32 pattern 32b, preferably comprising one single via 32. According to this example, each via 32 is separated from the neighbouring via(s) 32 by the pitches A and B substantially identical for each pattern repetition. The pitches A and B are preferably equal to one another.

The vias 32 can be repeated along a direction, preferably along the two distinct directions above, of the main extension plane of the first 30 and second 31 layers, over at least 80% of the dimension of the substrate 3 along this/these direction(s). The vias 32 are preferably repeated, in the main extension plane of the first layer 30, over at least 80%, preferably at least 90%, and even more preferably at least 95%, of the main extension plane of the first layer 30. The vias 32 are further preferably repeated, in the main extension plane of the substrate 3, over at least 80%, preferably at least 90%, and even more preferably at least 95%, of the main extension plane of the substrate 3. The generic substrate 3 thus comprises one or more generic via 32 matrices over a large part of its surface, to facilitate the manufacturing a microelectronic device as described in detail below. These vias 32 can, in particular, be selected according to the desired architecture, with a generic substrate 3 which can be adapted to manufacturing different microelectronic devices.

According to an example, at least some of the vias 32 and preferably each via, extends over a height greater than or equal to 50% of the thickness of the substrate 3, preferably greater than or equal to 70% of the thickness of the substrate 3.

According to an example being able to be illustrated by FIGS. 3A and 3B, the substrate 3 can comprise at least one and preferably more groove(s) 35 configured to improve the electrical isolation of the vias 32. The substrate 32 is thus particularly adapted for high-frequency applications, and/or in replacement of the high-resistivity substrate for the applications demanding it. For this, at least one via 32, and preferably each via 32, has a transverse cross-section fully surrounded by the groove 35, taken in the main extension plane of the first 30 and second 31 layers. The groove 35 can surround the via 32 over at least one portion of its longitudinal dimension L₃₂. The grooves 35 are preferably disposed so as to isolate the vias 32 from one another, a groove 35 preferably surrounding one single via 32. The grooves 35 preferably do not touch one another. The groove 35 can more specifically extend from the second layer 31 over a portion of the first layer 30.

Each groove 35 is preferably buried, i.e. that it does not open onto one or the other of the exposed surfaces 3a, 3b of the substrate 3. Each groove 35 therefore defines a closed volume. Each groove 35 is preferably hollow, it is not filled with a solid material. Each groove 35 is preferably filled with a gaseous atmosphere such as air, nitrogen or argon, optionally at a pressure less than or equal to the ambient pressure.

Each groove 35 is delimited by a side wall 350, a bottom wall 351 and an upper wall 352 opposite the bottom wall 351. The bottom wall 351 is disposed towards the back surface 3b of the substrate and the upper wall 352 is disposed towards the front surface 3a of the substrate 3. From among these walls, at least the bottom wall 351 and the side wall 350 can be made of dielectric material, for example, made of SiO₂. As FIG. 3A illustrates, all the walls can be made of dielectric material. According to a variant not represented in the drawings, the upper wall 352 can be made of the same material as the second layer 31. It can also be provided that the groove 35 is flush with the surface of the first layer 30, as the vias 32 illustrated in FIG. 2C. According to another variant being able, for example, to be illustrated by FIG. 3B, all the walls can be made of the same material as the layer in which or against which they extend, made of dielectric or semiconductive material according to the layer considered.

As illustrated, for example, by FIG. 3A, each groove 35 can have a longitudinal dimension, or equivalently a depth, L₃₅ substantially equal to or less than that of the via L₃₂, according to an example equal to plus or minus 5 μm.

As illustrated, for example, by FIGS. 3A and 3B, each groove 35 can have a transverse dimension D₃₅ taken on either side of the via 32, for example, a diameter, substantially less than or equal to 50 μm, preferably substantially between 20 μm and 30 μm. Each groove 35 can have a width substantially less than or equal to 5 μm, for example, substantially between 2 and 4 μm. Thus, similarly to the dimensions of the vias 32, an improvement of the electrical isolation can be obtained while making it possible to obtain a large via 32 density. Synergically, it is particularly advantageous to use these grooves 35 when the vias 32 are close to one another, as is the case for a high via 32 density on the substrate 3, in order to improve their electrical isolation. By high density, for example, the pitches A and/or B are less than or equal to 100 μm. It can be provided that the grooves 35 have equal or distinct dimensions between the different grooves 35.

According to the dimensions of the grooves 35 in the main extension plane of the first 30 and second 31 layers, the pitch can be adapted such that the grooves 35 are distinct from one another. Each groove 35 can be cylindrical, and preferably concentric to the via 32 that it surrounds.

As, for example, FIGS. 2A to 3C illustrate, the substrate 3 can comprise at least one mark, or equivalently, a marker 34 enabling the alignment of the substrate 3 with other elements. Thus, the placement of the vias 32 during the method for manufacturing the microelectronic device is made more reliable. This marker 34 can be formed by one or more dielectric material layer portion(s) at the first layer 30 and/or of the second layer 31. It is noted that a person skilled in the art can absolutely consider other variants of markers, like for example, a marking disposed on the front surface 3a or the back surface 3b of the substrate 3.

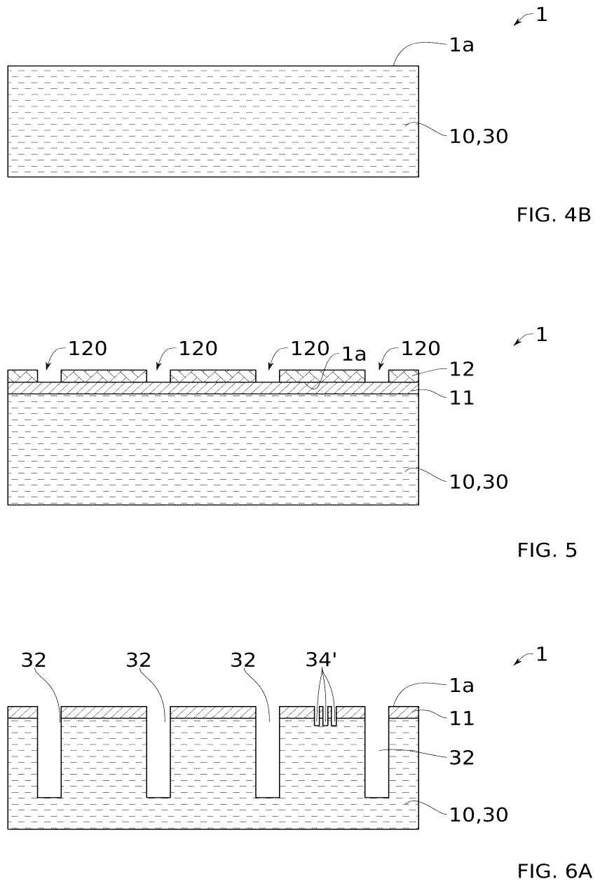

The method for manufacturing the substrate 3 is now described in reference to FIGS. 4A to 9B.

The method comprises the provision of a sub-substrate 1. The sub-substrate 1 comprises at least one first layer 10, intended to form the first layer 30 of the substrate 3 which will be obtained, as, for example, FIGS. 4A and 4B illustrate. The sub-substrate 1 can further comprise, as, for example, illustrated by FIG. 4A, a superficial layer 11 intended for form at least partially the second layer 31 of the substrate 3. The superficial layer 11 is preferably with the basis or made of a dielectric material. The sub-substrate 1 further has an exposed surface 1a, at the first layer 10 or at the superficial layer 11.

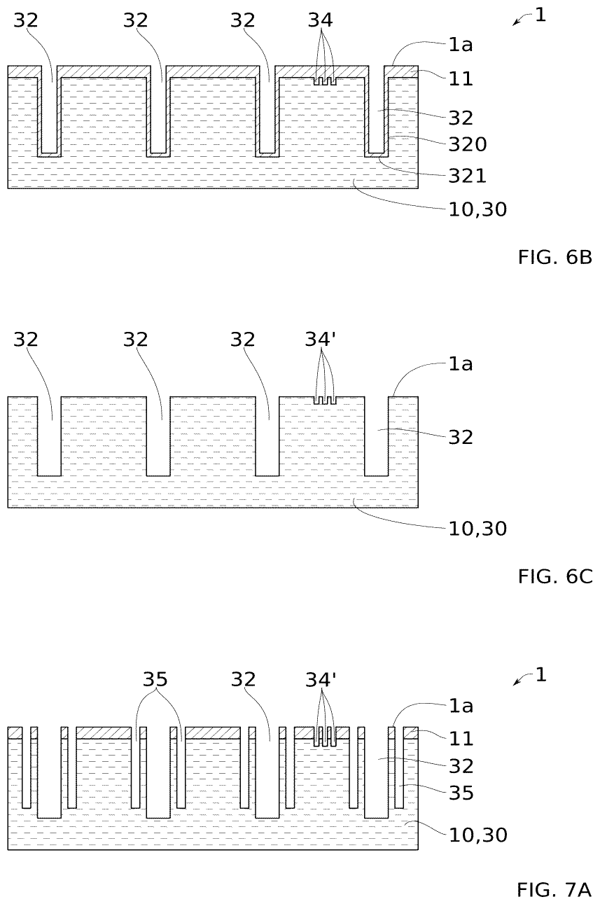

As, for example, illustrated by FIGS. 5 and 6A, 6C, the vias 32 can be formed by etching, and preferably by deep reactive ion etching (DRIE). To form the vias 32, the etching step can comprise the application of a mask 12 comprising openings 120 from which the vias 32 will be etched, as, for example, FIG. 5 illustrates. The mask 12 is preferably a resin mask. It can be provided that the mask is hard, for example, with the application of a resin mask 12, then the etching of the superficial layer 11, removing this mask and etching the first layer 10 thanks to the so-called “hard” oxide mask thus formed. It is noted that the superficial layer 11 can be removed after the etching of the vias 32, and the vias 32 electrically isolated by the subsequent deposition of a dielectric layer.

The etching is preferably configured to obtain the features of the vias 32 described above, and in particular, their dimensions and the pitches separating them. For example, the dimensions of the mask 12 and/or the etching time and etching speed are adjusted for this.

To form the vias 32, the method can then comprise a formation of a dielectric material at at least the bottom wall 321 and the bottom wall 320, as, for example, FIG. 6B illustrates.

This formation can be done by thermal oxidation, for example, at a temperature of substantially 1050° C. in an atmosphere comprising oxygen.

In a variant or complementarily, the dielectric material, for example, silica SiO₂, can be deposited at at least the walls 320, 321 of the vias 32. This deposition can be a chemical vapour deposition (CVD) from gaseous precursors comprising oxygen and silicon, for example, tetraethyl orthosilicate (TEOS) or silane of chemical formula SiH₄, optionally combined with dioxygen. The deposition is, for example, a sub-atmospheric CVD (SACVD), or a plasma-enhanced chemical vapour deposition (PECVD).

Preferably, the mask 12 is removed prior to the formation of these dielectric material walls. In the case where the layer 11 has served as a hard mask, it is preferable also to remove it.

Preferably, the formation of the walls 320, 321 is configured such that the dielectric material walls 320, 321 have a dimension substantially between 50 nm and 600 nm, and preferably substantially equal to 400 nm. For the side wall 320, this dimension is the transverse dimension. For the bottom wall 321, this dimension is the longitudinal dimension. For example, the thermal oxidation time or the deposition time and/or deposition speed can be adjusted for this.

The method can comprise, simultaneously or together with the etching of the vias 32 and, if necessary, with the formation of the dielectric material walls, a step of forming the marker 34. For this, the mask can further comprise openings, not represented in this case, to etch, for example, openings 34′ in the second layer 31 until in the first layer 30, illustrated, for example, in FIG. 6A. The openings 34′ can be filled with dielectric material during the formation of the walls. The formation of the marker 34 can be distinct from these steps, by the application, for example, of a mask specific to this marker 34, etching and filling of the openings 34′. If the formation of the marker 34 is distinct from these steps, it would be advantageously done before, to serve as a marker to the positioning of the vias 32.

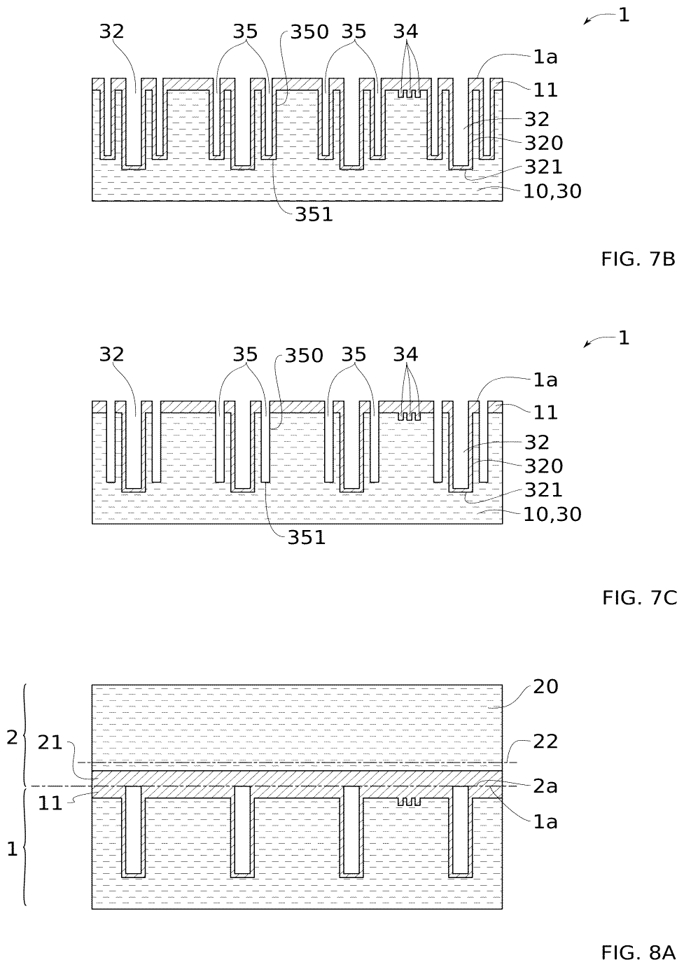

FIGS. 7A to 7C illustrate examples in which grooves 35 are formed around the vias 32. One single groove is represented to simplify the figures. The formation of the grooves 35 can comprise the same steps as for the etching of the vias 32 and, if necessary, for the formation of the dielectric material walls. The grooves 35 can be formed simultaneously at the vias 32, the mask 12 thus comprising openings corresponding to the grooves 35 to be etched. The grooves 35 can alternatively be etched before or after the etching of the vias 32, for example, by application of a mask and an etching specific to the grooves 35. According to an example, once the grooves 35 and vias 32 are etched, a dielectric material can be formed at the walls 350, 351, 320, 321 as described above. Alternatively, the grooves 35 can be formed after the formation of the dielectric material at the walls 320 and 321. It can be provided that another formation of dielectric material is done at the walls 350, 351, according to the methods described above. The etching of the grooves 35 can otherwise not be followed by a formation of dielectric material at the walls 350 and 351, as, for example, FIG. 7C illustrates. The grooves 35 and the vias 32 cannot have a dielectric material wall, according to a variant not illustrated.

Following the formation of the vias 32, and if necessary, of the grooves 35, these structures can be covered to be buried during the assembly of the sub-substrate 1 with a donor sub-substrate 2. The method can therefore comprise the provision of a donor sub-substrate 2 having an exposed surface 2a.

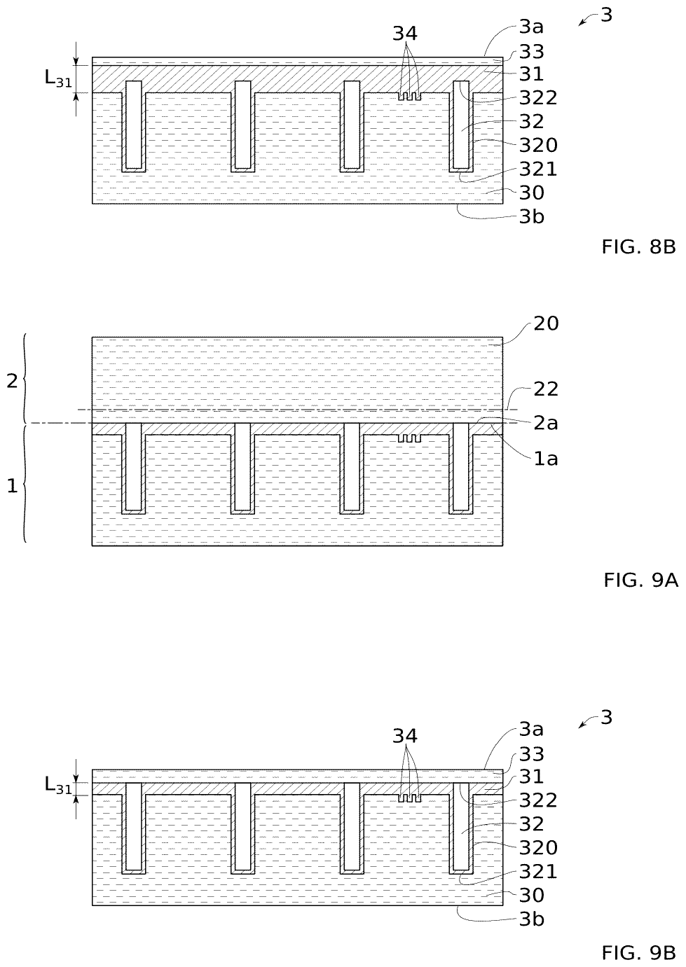

As illustrated by FIGS. 8A to 9C, the support 1 and donor 2 sub-substrates can be assembled by the contacting by direct bonding of their respective surfaces 1a, 2a. The donor substrate 2 can then be thinned, for example, by cleaving by the method known as Smart-Cut®.

The assembly can, for this, comprise, before the contacting of the surfaces 1a, 2a, the formation of an embrittlement zone 22 at a non-zero depth from the surface 2a of the donor sub-substrate 2. This embrittlement zone 22 is, for example, formed by ion implantation, such as hydrogen and/or helium ions. It is noted that any other technique of forming an embrittlement zone, and in particular, any other technique used in the SOI-type stack development methods, can be considered.

Following the assembly of the support sub-substrate 1 and of the donor sub-substrate 2, the method can comprise the separation of a superficial layer from the donor sub-substrate 2, at the embrittlement zone 22, as in the examples illustrated in FIGS. 8B and 9B. This separation can be done thermally or mechanically, according to steps known to a person skilled in the art.

Following the separation, the surface 3a obtained can be irregular and damaged. A polishing, chemical smoothing or chemical and/or mechanical and/or thermal curing, or atom cluster-based or monomer-based ion beam curing of the surface 3a can be done, such that the surface 3a has a crystalline quality and a roughness which is adapted for other subsequent methods. Any chemical mechanical polishing (CMP) or thermal polishing method intended to smooth a semiconductor-based, and in particular, silicon-based surface can be considered.

According to an example, the donor sub-substrate 2 comprises a layer 20 with the basis or made of a semiconductive material, for example, made of silicon and more specifically, made of monocrystalline silicon, or of a piezoelectric material. The donor sub-substrate 2 can further comprise a layer 21 with the basis or made of a dielectric material, for example, made of silica SiO₂.

According to an example being able to be illustrated by FIGS. 8A and 8B, the layer 21 can form the superficial layer of the donor sub-substrate 2. In particular, a semiconductive oxide, for example, silicon oxide against semiconductive oxide, for example, silicon oxide direct bonding can be done. Following their assembly, the layer 21 and the layer 11 will form the second layer 31 of the substrate 3. Their respective thicknesses can therefore be chosen to obtain the desired thickness L31. According to this example, it is understood that the upper wall 322 of the vias 32, and if necessary, the upper wall 352 of the grooves 35 can be formed of a dielectric material. The upper wall 322 of the vias 32 and, if necessary, the upper wall 352 of the grooves 35 can, for example, have a thickness substantially of between 1 nm and 600 nm.

According to an example being able to be illustrated by FIGS. 9A and 9B, the layer 20 can form the superficial layer of the donor sub-substrate 2. A semiconductive oxide, for example, silicon oxide, against semiconductor, and in particular silicon direct bonding can be done. Following their assembly, the layer 11 alone will form the second layer 31 of the substrate 3. Its thickness can therefore be chosen to obtain the desired thickness L₃₁. According to this example, it is understood that the upper wall 322 of the vias 32, and if necessary, the upper wall 352 of the grooves 35 can be formed of a semiconductive material.

According to an example being able to be illustrated by FIG. 9C, the layer 20 can form the superficial layer of the donor sub-substrate 2. A semiconductive or piezoelectric against semiconductor, and in particular silicon direct bonding can be done, when the layer 20 is based on a semiconductive or piezoelectric material. A semiconductive oxide against semiconductor, and in particular silicon direct bonding can be done, when the layer 20 is based on a dielectric material, and in particular, of an oxide. Following their assembly, the layer 20 will form the second layer 31 of the substrate 3. Its thickness can therefore be chosen to obtain the desired thickness L₃₁.

It is noted that it is preferable to have, for the assembly, a dielectric material thickness, and in particular, oxide thickness, of at least 10 nm at the bonding interface to avoid the appearance of defects.

The method for manufacturing a microelectronic device 4 is now described in reference to FIGS. 10 to 17.

In this method, the vias 32 can serve to establish interconnections. The vias 32 can alternatively or complementarily serve to form portions of a microelectronic device without necessarily being metal interconnections, for example, in a MEMS device. The vias can be intended to be filled with a semiconductive material, Poly-Si, for example.

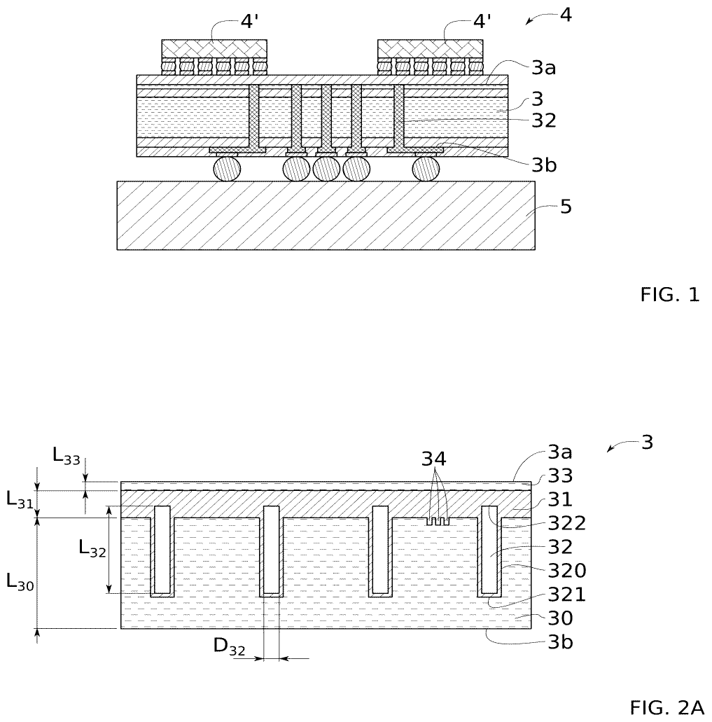

The method can comprise a provision of the substrate 3. The method can comprise the deposition of layers of components 4′ (illustrated in FIG. 1), for example, transistors, diodes, memory points. This deposition can, for example, comprise FEOL steps.

As, for example, illustrated in FIG. 10, the method can comprise the deposition of at least one layer portion 40, also called device portion 40, on the front surface 3a of the substrate 3. Below, it is considered, in a non-limiting manner, that several portions 40 are deposited. Alternatively or complementarily, the device portion(s) can be etched in the front exposed surface 3a of the substrate 3.

These portions can be metal 40 and can, in particular, form metal interconnecting lines. Typically, these metal portions 40 can serve to redistribute electrical signals. These metal portions can also be called metallisation levels. There can be several metal portions 40 with interconnections between these portions. This deposition can, for example, comprise BEOL steps.

Below, it is considered, in a non-limiting manner, that these portions 40 are metal and that the etched via 32 serves to establish an interconnection. The following steps absolutely apply to the case where non-metal device 4 portions 40 are deposited and/or etched, and/or where a semiconductive member 45 is produced in the via 32.

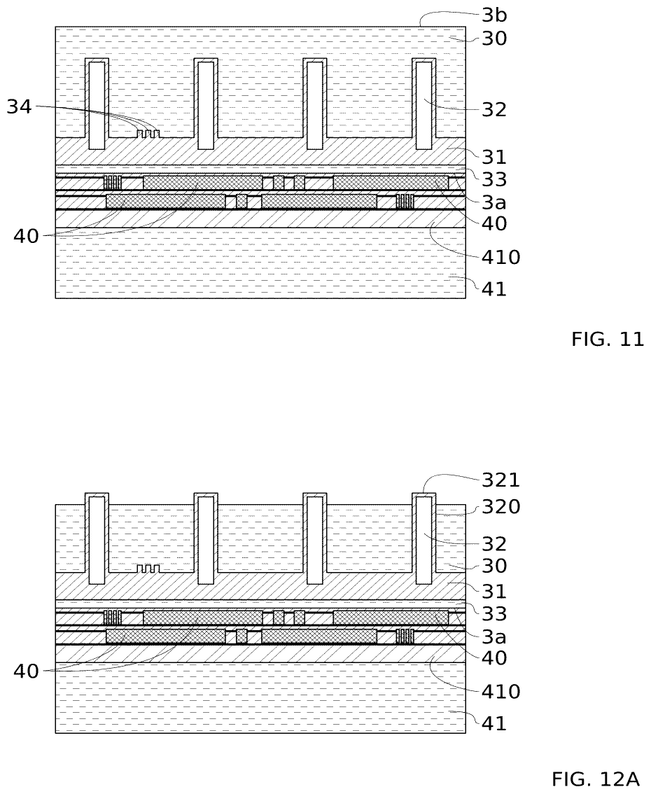

In order to facilitate the handling of the substrate 3, the method can comprise the mounting of a support 41 on the side of the exposed front surface 3a of the substrate 3, for example, through a bonding 410 done on the preceding depositions, as illustrated by FIG. 11, for example. This further makes it possible to protect the depositions done on the front surface 3a of the substrate 3.

After the deposition of the metal portions 40, if necessary after the mounting of the support 41, the method comprises the etching of at least one via 32, in order to achieve at least one interconnection with one of the metal portions 40. For this, several examples are possible and are now described. Below, it is considered in a non-limiting manner that several vias 32 are etched and filled.

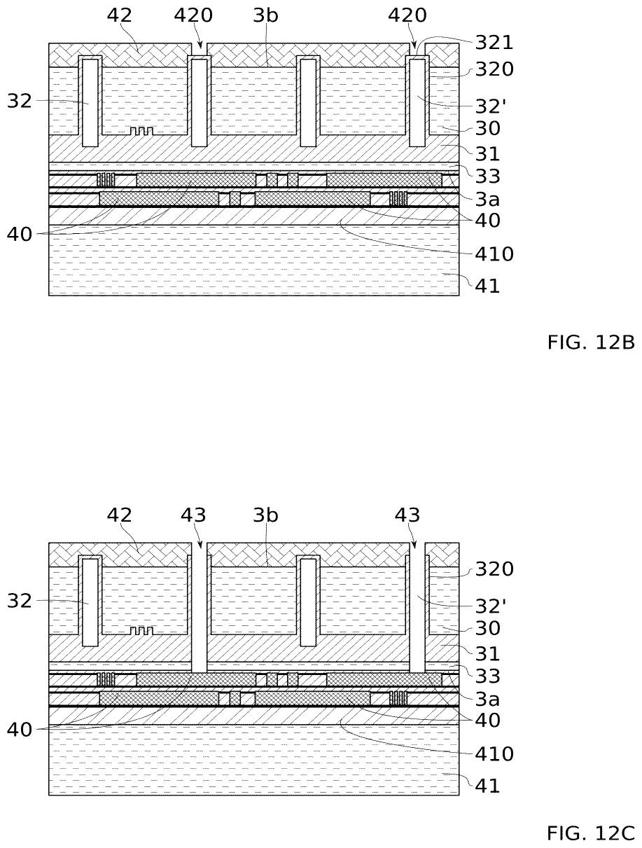

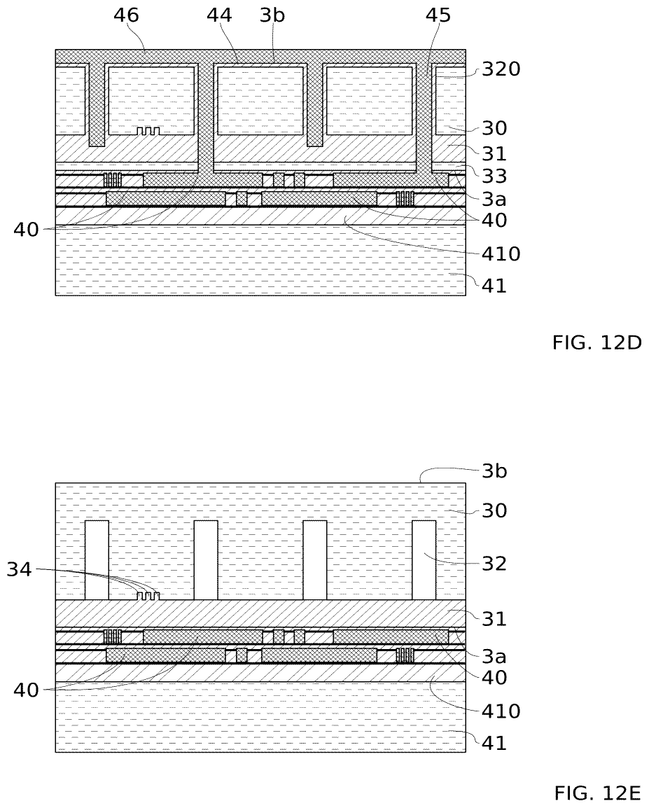

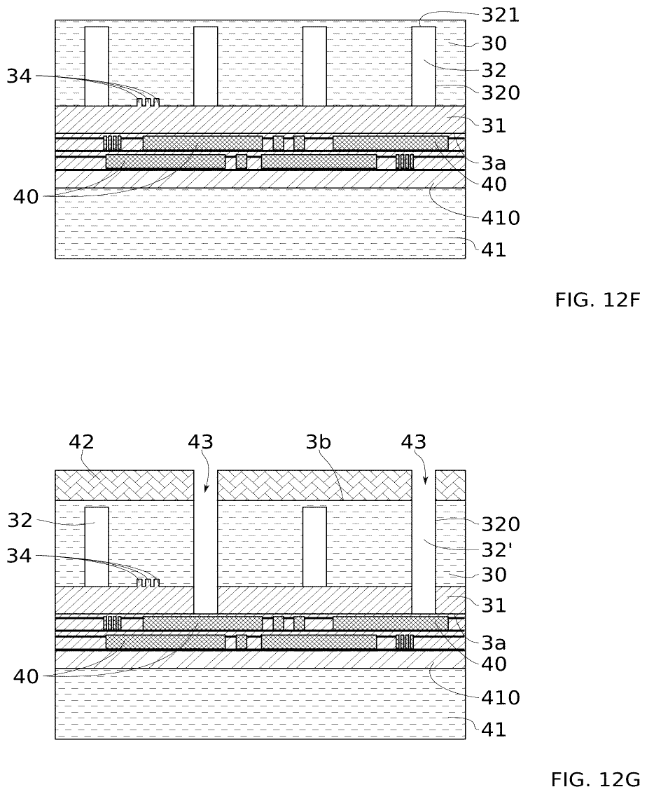

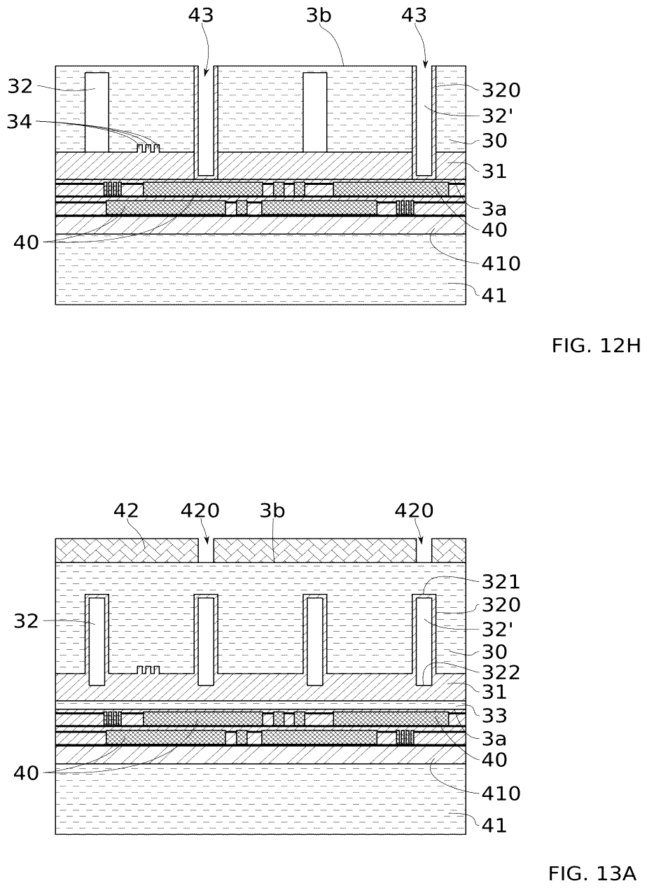

According to a first example, as illustrated by FIGS. 12A, 12E and 12F, from the back surface 3b of the substrate 3, the first layer 30 can be etched until being flush with, or exceeding the bottom wall 321 of the vias 32. The bottom wall 321 of the vias 32 is thus exposed. For this, the first layer 30 can be thinned and etched by a selective etching of the material of the first layer 30 with respect to the dielectric material of the walls 320, 321. According to the example illustrated in FIG. 12A, the etching can, for example, be a selective etching of silicon with respect to silica SiO₂ in reactive ion etching using a precursor such as SF₆. By “selective etching of a material A with respect to a material B”, this means that the etching speed of the material A is 10, and preferably 100 times greater than that of the material B. The carrying out of a partial mechanical thinning of the substrate 3 ended by a selective plasma or chemical etching can also be considered.

The dielectric material wall can then be etched selectively with respect to the material of the first layer 30, to open into the via 32.

If it is sought to only etch then fill some of the vias 32, in particular when the substrate 3 is a generic substrate comprising a via 32 matrix, the method can comprise a selection of vias 32′ to be etched. As, for example, illustrated by FIGS. 12B and 12G, a mask 42 can be deposited on the back surface 3b of the substrate 3. This mask 42 can comprise openings 420 located in vertical alignment with the vias 32′ to be etched. The walls 321 can then be etched by the opening, to open into the vias 32.

Whether all or some of the vias 32 are etched, the etching can be continued to form at least one cavity 43, for example, an electrical connecting cavity 43 extending from the via 32 until the portion 40 located below the via 32, as, for example, illustrated in FIGS. 12C and 12G. Below, it is considered in a non-limiting manner, that several cavities 43 are formed. For example, the etching of the dielectric material at the wall 321 can be a reactive ion etching. The etching of the semiconductive material at the wall 321 can be similar to that done to etch the layer 30.

When the walls of the vias 32′ to be etched are not made of dielectric material, the method can comprise the formation of a dielectric layer at at least the side wall 320, according to the methods described above in reference to the method for manufacturing the substrate 3. This example can be illustrated by FIG. 12H.

Once the cavities 43 are formed, the method can comprise an electrically conductive or semiconductive member 45. This member 45 can with the basis or made of a metal material 45, for example, electrolytic copper or CVD tungsten. Alternatively, this member 5 can be with the basis or made of a semiconductive material, for example, poly-Si. The deposition can be configured so as to fill these cavities 43 of the metal material to form an electrical interconnection or a device portion 4, as, for example, illustrated by FIG. 12D. The deposition can further be configured so as to further cover by a metal or semiconductive layer 46 at least one portion of the back exposed surface 3b of the substrate 3.

Between the formation of the cavities 43 and the deposition of the member 45, the method can comprise at least one from among:
the removal of the mask 42,
a passivation of the exposed back surface 3b of the substrate 3, for example, by formation of a dielectric material layer 44, also called passivation layer 44. This formation can be done by deposition of a dielectric material, for example, as described above,
an etching of the cavities 43, so as to remove an optional oxide layer, which would be formed at the bottom of the cavity, in particular during the formation of the passivation layer 44. This optional oxide layer can indeed limit the electrical recontacting on the portion 40.

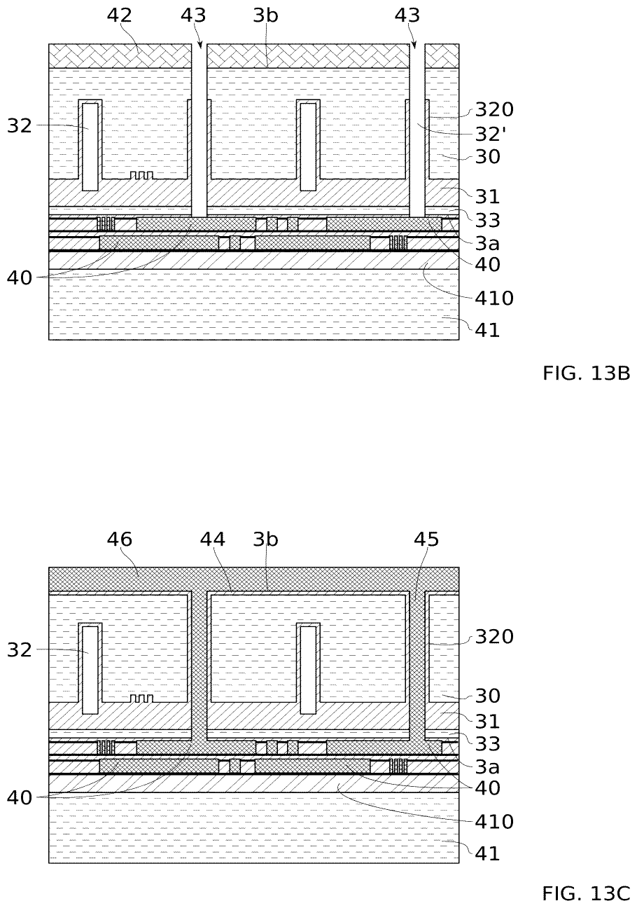

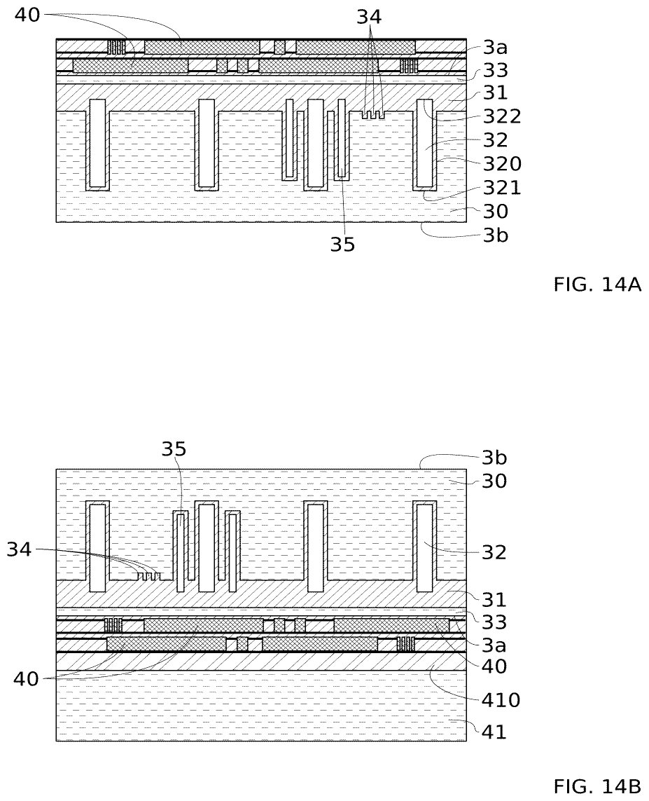

According to a second example illustrated by FIGS. 13A to 13C, the mask 42 can first be deposited on the back surface 3b of the substrate 3. This mask 42 can comprise openings 420 located in vertical alignment with the vias 32. If it is sought to only etch then metallise some of the vias 32, in particular when the substrate 3 is a generic substrate comprising a via 32 matrix, the selection of vias 32′ to be etched can be done by the arrangement of the openings 420 above the vias 32′ to be etched.

The first layer 30 can be etched by the openings 420 until being flush with, even exceeding the bottom wall 321 of the vias. The etching can be continued to form at least one cavity 43 extending from the via 32 until the metal portion 40 located below the via 32, as, for example, illustrated in FIG. 13B. In this case, also, it is considered in a non-limiting manner that several cavities 43 are formed. This etching step can be a reactive ion etching.

The subsequent steps can then be carried out as described above, as FIG. 13C illustrates, for example. The layer 44 thus also passivates the top of the cavities 43, in continuity of the side wall 320.

This example of an embodiment is also applicable when the vias 32′ do not have a dielectric material wall. As described above, the method can comprise the formation of a dielectric layer at at least the side wall 320 after the opening of the vias 32′ to be etched.

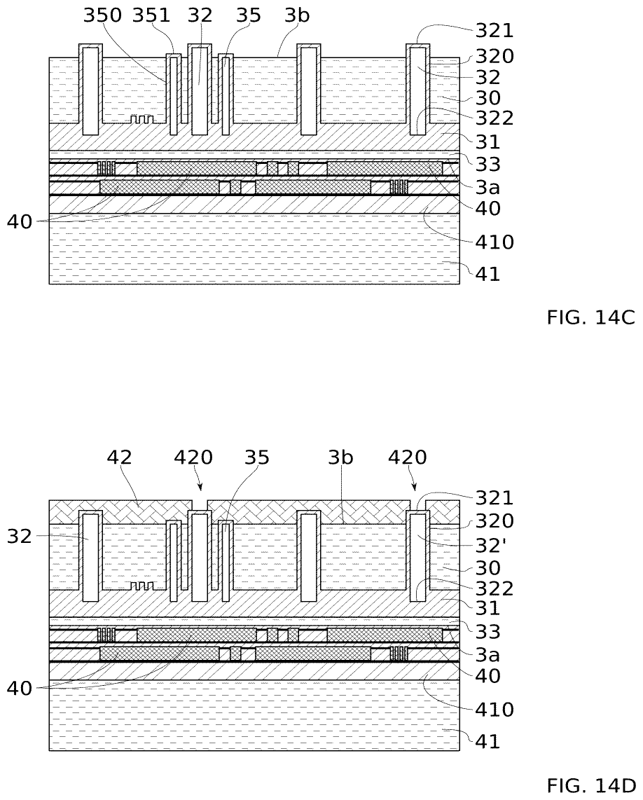

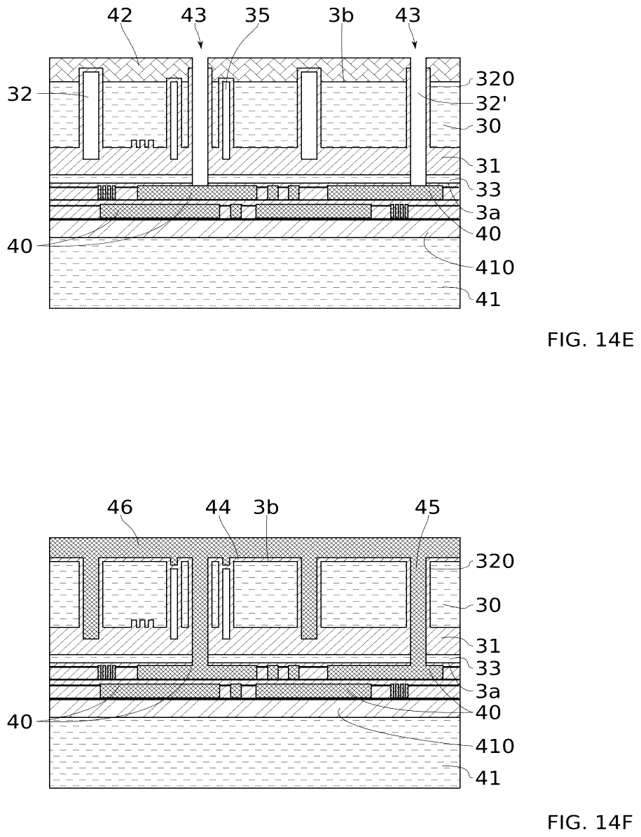

When the substrate 3 comprises grooves 35, the two examples described above can apply. FIGS. 14A to 14F illustrate the first example described above. According to one or the other of these examples, in order to not fill the grooves of the conductive or semiconductive member, the openings 420 of the mask 42 can be disposed so as to not enable the etching of the grooves 35. More specifically, the mask can cover the back surface 3b of the substrate in vertical alignment with the grooves 35, as illustrated, for example, in FIG. 14D. During steps subsequent to the formation of the cavities 43, the grooves 35 preferably remain closed and are not therefore filled with the member 45.

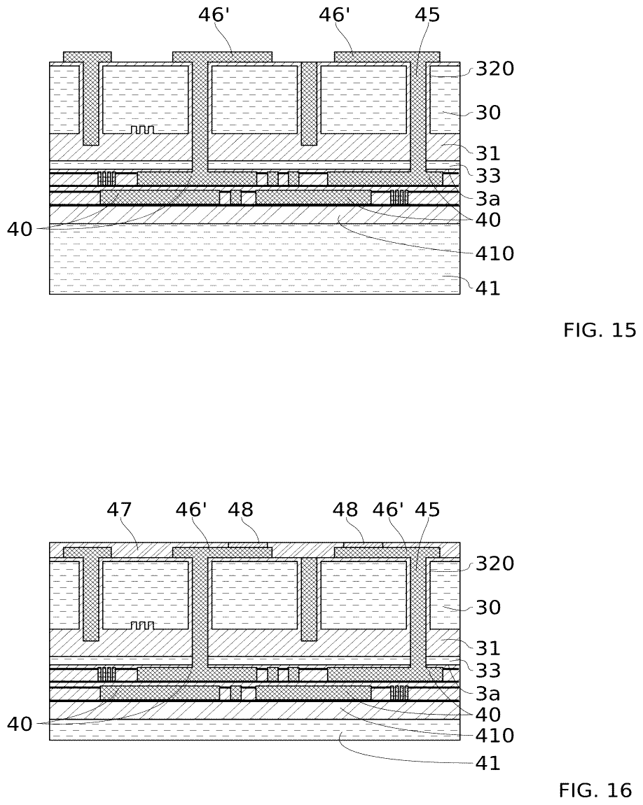

Following the deposition of a metal layer 46 on the back surface 3b of the substrate, whatever the example of an embodiment described above, the method can comprise a production of patterns 46′ in this metal layer 46, for example, to delimit different interconnections. This can be illustrated as an example by FIG. 15. This pattern production can be done by masking, followed, for example, by an ion etching or by ion beam etching or by wet etching.

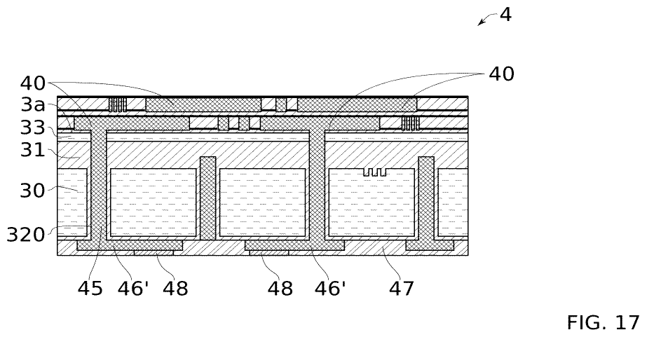

The method can comprise, alternatively or complementarily with this production of patterns 46′, a passivation 47 of the back surface 3b of the substrate, as FIG. 16 illustrates, for example. This passivation can be done by deposition of an organic compound such as a photosensitive construction resin, for example, of the polyimide or benzocyclobutene polymer type.

As FIG. 16 illustrates, for example, the method can further comprise a so-called UBM (under bump metallisation), so as to connect the electrical interconnections obtained and the casing 5 illustrated in FIG. 1.

Once the manufacturing steps taking place on the back surface 3b of the substrate 3 have ended, the support 41 can be dismounted as the passage from FIG. 16 to FIG. 17 illustrates.

In view of the description above, it clearly appears that the invention proposes a substrate, its manufacturing method and a method for manufacturing a microelectronic device making it possible to facilitate the manufacturing of vias in a microelectronic device.

The invention is not limited to the embodiments described above and extends to all the embodiments covered by the invention. The present invention is not limited to the examples described above. Many other variants of embodiments are possible, for example, by combining features described above, without moving away from the scope of the invention. Furthermore, the features described relating to an aspect of the invention can be combined with another aspect of the invention. In particular, the substrate can have any feature resulting from its manufacturing method and vice versa, this method can comprise any step configured to obtain a feature of the substrate. The method for manufacturing a microelectronic device can implement any feature of the substrate.

In the examples described, the semiconductive material is silicon. It is noted that the invention can absolutely apply to other mono- or polycrystalline semiconductors, optionally doped, and in particular, to Si, Ge, SiGe, SiC, III-V material (for example, AlN, GaN, InN, InGaAs, GaP, InP, InAs, AsGa, etc.), and II-VI material semiconductors. The dielectric material can be an oxide or a semiconductive nitride, for example, SiO₂, SiN, Al₂O₃. The piezoelectric material can, as an example, be chosen from among lithium tantalate (LiTaO₃), lithium niobate (LiNbO₃), potassium sodium niobate (KₓNa₁₋ₓNbO₃ or KNN), barium titanate (BaTiO₃), quartz, lead zirconate titanate (PZT), a lead magnesium and lead titanate niobate compound (PMN-PT), zinc oxide (ZnO), aluminium nitride (AlN) or aluminium scandium nitride (AlScN), other materials naturally being able to be considered.

1.-24. (canceled)

25. A substrate, comprising:
a first layer based on a semiconductive material;
a second layer surmounting the first layer; and
a plurality of buried vias extending from the second layer over a portion of the first layer, each via of the plurality of buried vias being delimited by a side wall, a bottom wall, and an upper wall opposite the bottom wall, said each via having at least one transverse dimension less than or equal to 30 μm.

26. The substrate according to claim 25, wherein at least the bottom wall and the side wall are made of dielectric material.

27. The substrate according to claim 25, wherein the second layer is a layer based on a material chosen from among a dielectric material, a semiconductive material, or a piezoelectric material.

28. The substrate according to claim 25, wherein at least some of the vias has an aspect ratio greater than or equal to 10, of longer dimensions oriented along a dimension in thickness of the first layer and the second layer.

29. The substrate according to claim 25,
wherein the plurality of vias forms a periodic matrix, and
wherein the vias are separated in pairs by a constant pitch along at least one direction of a main extension plane of the first layer and the second layer, the constant pitch being between 50 μm and 300 μm.

30. The substrate according to claim 25, wherein at least one via over at least one portion of a longitudinal dimension of the at least one via, is fully surrounded by a groove extending from the second layer over a portion of the first layer.

31. A method for manufacturing a substrate according to claim 25, the method comprising:
providing a support sub-substrate comprising at least one first layer based on a semiconductive material, the support sub-substrate having an exposed surface;
etching of a plurality of vias such that the plurality of vias extend from the exposed surface over a portion of the first layer, each via of the plurality of vias being delimited by a side wall and a bottom wall, said each via of the plurality of vias having at least one transverse dimension less than or equal to 30 μm;
providing a donor sub-substrate comprising a superficial layer having an exposed surface; and
assembling of the support sub-substrate and the donor sub-substrate by their exposed surfaces, so as to cover the plurality of vias, said each via of the plurality of vias thus being delimited by the side wall, the bottom wall, and an upper wall opposite the bottom wall.

32. The method according to claim 31, wherein, following the etching of the plurality of vias, the method further comprises, for said each via of the plurality of vias, forming a dielectric material at at least the bottom wall and the side wall.

33. The method according to claim 32, wherein the forming the dielectric material at at least the bottom wall and the side wall of the plurality of vias comprises:
a thermal oxidation step so as to oxidise a semiconductive material of the first layer at at least the bottom wall and the side wall, and/or
depositing the dielectric material at at least the bottom wall and the side wall.

34. The method according to claim 31, wherein the superficial layer of the donor sub-substrate is a layer based on a material chosen from among a dielectric material, a semiconductive material, or a piezoelectric material.

35. The method according to claim 31, wherein:
the support sub-substrate further comprises a superficial layer based on a dielectric material surmounting the first layer, the superficial layer having the exposed surface, and/or
the superficial layer of the donor sub-substrate is a layer based on a dielectric material surmounting a layer based on a material chosen from among a semiconductive material or a piezoelectric material.

36. A method for manufacturing a microelectronic device, the method comprising:
providing a substrate according to claim 25, the substrate having a front exposed surface and a back exposed surface;
forming at least one layer portion of the microelectronic device by a deposition, on the front exposed surface of the substrate, of the at least one layer portion, and/or etching of the front exposed surface of the substrate, configured so as to form the at least one layer portion;
etching, at at least one via, by the back exposed surface of the substrate, in which a wall from among the upper wall and the bottom wall of the at least one via is etched, so as to open into the via, then continue the etching to reach the at least one layer portion of the microelectronic device, to form a cavity; and
depositing an electrically conductive or semiconductive member, so as to fill the cavity.

37. The method according to claim 36, further comprising, prior to the etching by the back exposed surface of the substrate, selecting at least one via to be etched from among the plurality of vias, only some of the plurality of vias being selected as the via to be etched, the selecting of the at least one via to be etched comprising:
applying, on the back exposed surface of the substrate, a mask comprising openings located in vertical alignment with the at least one via to be etched, and
etching the first layer, so as to reach the wall of the at least one via to be etched.

38. The method according to claim 37, wherein the selecting the at least one via to be etched further comprises applying the mask, then etching of the first layer through the openings of the mask.

39. The method according to claim 37, wherein the selecting the at least one via to be etched further comprises the etching of the first layer, so as to reach the wall of the at least one via to be etched, then applying the mask.

40. The method according to claim 36, wherein the depositing the electrically conductive or semiconductive member is configured so as to further cover, by an electrically conductive or semiconductive layer, at least one portion of the back exposed surface of the substrate.

41. The method according to claim 36, further comprising:
between the forming the at least one layer portion of the microelectronic device, and the etching by the back exposed surface of the substrate, mounting of a support on the front exposed surface of the substrate; and
after the depositing the electrically conductive or semiconductive member, so as to fill the cavity, dismounting of the support.
